(19) United States
(12) Patent Application Publication
(10) Pub. No.: US 2016/0208415 A1
(43) Pub. Date: Jul. 21, 2016

(54) MAGNETIC FIELD GUIDED CRYSTAL ORIENTATION SYSTEM FOR METAL CONDUCTIVITY ENHANCEMENT

(71) Applicant: APPLIED MATERIALS, INC., Santa Clara, CA (US)

(72) Inventors: Christopher Dennis Bencher, Cupertino, CA (US); Peng Xie, Fremont, CA (US); Stephen Moffatt, Jersey Channel Islands (GB); Bruce E. Adams, Portland, OR (US); Majeed A. Foad, Sunnyvale, CA (US)

(21) Appl. No.: 14/908,505

(22) PCT Filed: Aug. 19, 2014
(86) PCT No.: PCT/US2014/051747

§ 371 Date: Jan. 28, 2016

Related U.S. Application Data
(60) Provisional application No. 61/867,557, filed on Aug. 19, 2013.

(51) Int. Cl. C30B 30/04; C30B 19/08; C30B 29/02

(52) U.S. Cl. CPC C30B 30/04; C30B 29/02; C30B 19/08

(57) ABSTRACT

A magnetic field guided crystal orientation system, and a method of operation of a magnetic field guided crystal orientation system thereof, including: a work platform; a heating element above the work platform for selectively heating a base layer having grains on a wafer substrate where the wafer substrate is a part of a wafer on the work platform; and a magnetic assembly fixed relative to the heating element for aligning the grains of the base layer using a magnetic field of 10 Tesla or greater for formation of an interconnect having a crystal orientation of grains in the interconnect matching the crystal orientation of the grains of the base layer.

### CROSS-REFERENCE TO RELATED APPLICATION(S)

This application claims the benefit of U.S. Provisional Patent Application Ser. No. 61/867,557 filed Aug. 19, 2013, and the subject matter thereof is incorporated herein by reference thereto.

### TECHNICAL FIELD

The present invention relates generally to a crystal orientation system, and more particularly to a system for controlling the orientation of metal crystals.

### BACKGROUND

Semiconductor chips have become progressively more complex, driven in large part by the need for increasing processing power in a smaller chip size for compact or portable electronic devices such as cell phones, smart phones, personal media systems, ultraportable computers.

As sizes of every component of the semiconductor chips decreases, the speed of an electrical signal can actually begin to slow down due to a phenomenon known as RC Delay. R stands for resistance and C stands for capacitance. As sizes decrease, the RC Delay starts to go up very quickly because of both increasing resistance (from the metal films) and increasing capacitance (from the smaller dimensions). One of the major factors driving the increased metal resistance is the smaller metal grain sizes which are constrained by narrower trenches necessitated by decreasing sizes. The smaller grains have greater relative volume of grain boundaries which cause electron scattering during signal transport. RC Delay is caused by grain boundary scattering. Metals solidify into crystals, or grains, and between each grain is a grain boundary. As interconnects within the chip get smaller, the number of grain boundaries that need to be crossed also increases, increasing RC Delay.

It is known that metal grains can be induced to grow in a particular orientation given a seed crystal. In addition, metal grains which are even partially aligned reduce grain boundary scattering. However, at the nanometer scale on a wafer with millions upon millions of transistors it is not feasible to touch a seed crystal down on every surface which requires the growth of a metal interconnect.

Thus, a need still remains for a method of reducing the grain boundary scattering induced RC Delay. In view of the push towards smaller and smaller technology nodes, it is increasingly critical that answers be found to these problems. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### SUMMARY

The present invention provides a method of operation of a magnetic field guided crystal orientation system of a magnetic field guided crystal orientation system that includes providing a wafer including a wafer substrate; depositing a base layer having grains on the wafer substrate; aligning the crystal orientation of the grains of the base layer using a magnetic field of 10 Tesla or greater; and forming an interconnect on the base layer, the crystal orientation of the grains in the interconnect matching the crystal orientation of the grains of the base layer.

The present invention provides a magnetic field guided crystal orientation system that includes a work platform; a heating element above the work platform for selectively heating a base layer having grains on a wafer substrate where the wafer substrate is a part of a wafer on the work platform; and a magnetic assembly fixed relative to the heating element for aligning the grains of the base layer using a magnetic field of 10 Tesla or greater for formation of an interconnect having a crystal orientation of grains in the interconnect matching the crystal orientation of the grains of the base layer.

Certain embodiments of the invention have other steps or elements in addition to or in place of those mentioned above. The steps or element will become apparent to those skilled in the art from a reading of the following detailed description when taken with reference to the accompanying drawings.

### BRIEF DESCRIPTION OF THE DRAWINGS

FIG. 1 is an isometric view of a magnetic field guided crystal orientation system in a first embodiment of the present invention.

FIG. 2 is an isometric view of the magnetic field guided crystal orientation system in a second embodiment of the present invention.

FIG. 3 is an isometric view of the magnetic field guided crystal orientation system in a third embodiment of the present invention.

FIG. 4 is a cross-sectional view of the magnetic field guided crystal orientation system in a fourth embodiment of the present invention.

FIG. 5 is a detailed cross-sectional view of the wafer in a base layer deposition phase of operation.

FIG. 6 is the structure of FIG. 5 in a base layer alignment phase of operation.

FIG. 7 is the structure of FIG. 6 in a second deposition phase of operation.

FIG. 8 is an example of aligned grains of a portion of the interconnect.

FIG. 9 is another example of aligned grains of a portion of the interconnect.

FIG. 10 is the magnetic field guided crystal orientation system in a fifth embodiment of the present invention.

FIG. 11 is a flow chart of a method of operation of a magnetic field guided crystal orientation system in a further embodiment of the present invention.

### DETAILED DESCRIPTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

Where multiple embodiments are disclosed and described having some features in common, for clarity and ease of illustration, description, and comprehension thereof, similar and like features one to another will ordinarily be described with similar reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the wafer, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures. The term “on” means that there is direct contact between elements. The term “directly on” means that there is direct contact between one element and another element without an intervening element.

The term “preferred metal direction” as used herein is defined as the primary direction of the metal interconnect pattern. In a device having multiple levels of interconnects, each interconnect level has a preferred direction or alignment for metal grains which matches up with the directionality of the majority of the interconnect pattern.

The term “active side” refers to a side of a die, a module, a package, or an electronic structure having active circuitry fabricated thereon or having elements for connection to the active circuitry within the die, the module, the package, or the electronic structure.

The term “processing” as used herein includes deposition of material or photoresist, patterning, exposure, development, etching, cleaning, and/or removal of the material or photoresist as required in forming a described structure.

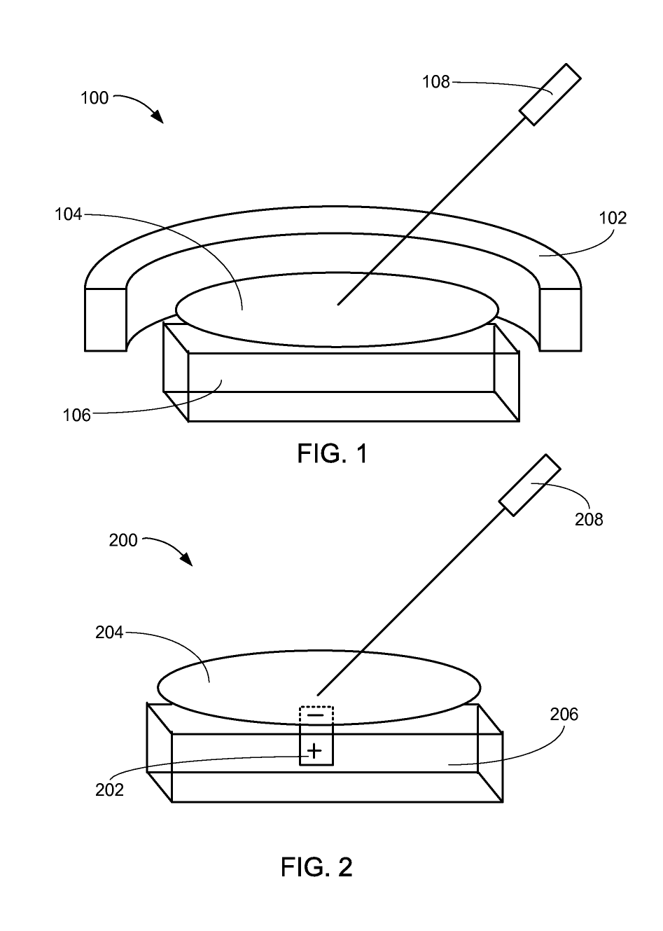

Referring now to FIG. 1, therein is shown an isometric view of a magnetic field guided crystal orientation system 100 in a first embodiment of the present invention. This view shows a magnetic assembly 102, a wafer 104, a work platform 106, and a heating element 108, which are all inside a containment chamber (not shown). The containment chamber is airtight and can be filled with any combination of gases necessary, such as nitrogen, hydrogen, oxygen, argon, helium, other noble gases, or a combination thereof, or the containment chamber can be under a vacuum or near-vacuum. Only a portion of the magnetic assembly 102 is shown for clarity. The wafer 104 can be at least 200 mm in diameter and is located centrally within the magnetic assembly 102, which in this example is a “barrel” magnet that circles the wafer. A barrel magnet is a circular magnet with a hole in the center, and is shown in a cutaway view so other elements are easily visible. The wafer 104 and the magnetic assembly 102 are fixed with respect to each other on the work platform 106, which is sometimes also called a scaffolding structure.

The heating element 108 is capable of generating a beam or heating a specific targeted area that can have any cross-sectional shape such as circular, oval, a rectangular or square shape, or polygonal. The heating element 108 can operate in various ways. For example, the heating element 108 can be a laser emitter, an argon beam emitter for physical vapor deposition, electron beam, or a gas cluster ion beam (GCIB). Also for example, the heating element 108 can be a microwave emitter, induction heater, a flash/arc lamp, a broad wavelength flash lamp, or conductive coupling. While other types of beams or heating techniques are possible depending on what is used for the heating element 108, a laser beam is preferred because the laser beam is not affected by magnetic fields. In this example, the laser beam is represented by a solid line extending from the heating element 108 to the wafer 104. It is understood that the solid line can also represent the path of other electromagnetic emissions (ion beam, electron beam, microwaves, etc.).

The laser beam can be generated from the heating element 108 at various wavelengths. The laser beam can be pulsed, continuous wave, or quasi-continuous wave. The work platform 106 can move relative to the heating element 108 to allow full coverage of the wafer 104, and is capable of moving in any direction necessary such as up and down and any kind of lateral movement, in order to position the wafer 104 relative to the laser beam for precisely targeting particular portions of the wafer. The magnetic assembly 102 is capable of generating a magnetic field with a strength of 10 T (Tesla) or more. The magnetic assembly 102 can generate the magnetic field as a static field or as a pulsed magnetic field which is synchronized with the laser beam from the heating element 108. The magnetic assembly 102 as a barrel magnet can apply the magnetic field across all of the wafer 104 simultaneously. As an example, rather than a single barrel magnet, two opposing toroidal magnets may also be used. The opposing toroidal magnets can compress the magnetic field strength along their common axis while leaving an open space for a laser or other beam to pass through.

It has been discovered that using a barrel magnet as the magnetic assembly 102 simplifies the use of the magnetic field guided crystal orientation system 100, improving reliability and throughput. Because the magnetic assembly 102 is capable of covering all of the wafer 104 at the same time, the magnetic assembly 102 can be fixed directly on the work platform without requiring a separate mount inside the magnetic field guided crystal orientation system 100. The fixed location of the magnetic assembly 102 laterally surrounding the wafer 104 also precludes the magnetic assembly 102 from occluding the laser beam from the laser emitter, allowing a laser emitter to be positioned at any angle necessary relative to the wafer 104. In the case a barrel magnet is used, an arc lamp or flash lamp can treat the entire wafer simultaneously and the barrel magnet can be positioned to have a magnetic field going through the wafer at the same orientation throughout, which can also increase efficiency and throughput.

Referring now to FIG. 2, therein is shown an isometric view of the magnetic field guided crystal orientation system 200 in a second embodiment of the present invention. This view shows a magnetic assembly 202, a wafer 204, a work platform 206, and a heating element 208, which are all inside a containment chamber (not shown). The containment chamber is airtight and can be filled with any combination of gases necessary, such as nitrogen, hydrogen, oxygen, argon, helium, other noble gases, or a combination thereof. Only a portion of the magnetic assembly 202 is shown for clarity. The wafer 204 can be at least 200 mm in diameter and is located above the magnetic assembly 202, which is a magnet mounted below the wafer 204. The wafer 204 is fixed to the work platform 206 while the magnetic assembly 202 is fixed to a separate magnet mount.

The heating element 208 is mounted in a fixed position relative to the magnetic assembly 202 and is capable of generating a beam that can have any cross-sectional shape such as circular, oval, a rectangular or square shape, or polygonal. The heating element 208 can operate in various ways. For example, the heating element 208 can be a laser emitter, an argon beam emitter for physical vapor deposition, electron beam, or a gas cluster ion beam. Also for example, the heating element 208 can be a microwave emitter, induction heater, a flash/arc lamp, a broad wavelength flash lamp, or conductive coupling. While other types of beams or heating techniques are possible depending on what is used for the heating element 208, a laser beam is preferred because the laser beam is not affected by magnetic fields. While other types of beams or heating techniques are possible depending on what is used for the heating element 208, a laser beam is preferred because the laser beam is not affected by magnetic fields. In this example, the laser beam is represented by a solid line extending from the heating element 208 to the wafer 204. It is understood that the solid line can also represent the path of other electromagnetic emissions (ion beam, electron beam, microwaves, etc.).

A laser beam can be generated from the heating element 208 at various wavelengths. The laser beam can be pulsed, continuous wave, or quasi-continuous wave. The work platform 206 can move relative to the heating element 208 and the magnetic assembly 202 to allow full coverage of the wafer 204, and is capable of moving in any direction necessary such as up and down and any kind of lateral movement, in order to position the wafer 204 relative to the laser beam for precisely targeting particular portions of the wafer 204. The heating element 208 is fixed relative to the magnetic assembly 202 so as to have the laser beam illuminate the same spot on the wafer 204 that the magnetic assembly 202 covers with a magnetic field.

The magnetic assembly 202 is capable of generating the magnetic field with a strength of 10 T (Tesla) or more. The magnetic assembly 202 can generate the magnetic field as a static field or as a pulsed magnetic field which is synchronized with the laser beam from the heating element 208. The magnetic assembly 202 can apply the magnetic field uniformly across a localized portion of the wafer 204. In this example, the magnetic assembly 202 can be fixed relative to the work platform 206. The magnetic assembly 202 is marked with a plus and minus sign for ease of identification only, and the orientation of the plus and minus signs is not meant to be limiting.

It has been discovered that the use of the heating element 208 to generate the laser beam to illuminate a portion of the wafer 204 that is covered by the magnetic field generated by the magnetic assembly 202 allows the simultaneous melt and induction of a preferred crystal orientation upon resolidification of specific types of paramagnetic or diamagnetic metals, such as copper, without the use of a seed crystal. It is understood by one or ordinary skill in the art that alignment of paramagnetic and diamagnetic metals are also considered non-magnetic. However, under the magnetic field of 10 T or greater, even weakly diamagnetic materials will crystallographically orient in a specific direction upon solidification. It has also been found to be advantageous to perform a stair-case reduction in temperature as the resolidification cooling takes place. For example, the laser pulses (or arc lamp flashes) may be delivered such that a first pulse (or set of pulses) melts the metal, and then a series of decreasing intensity pulses is delivered to engineer specific cooling profiles.

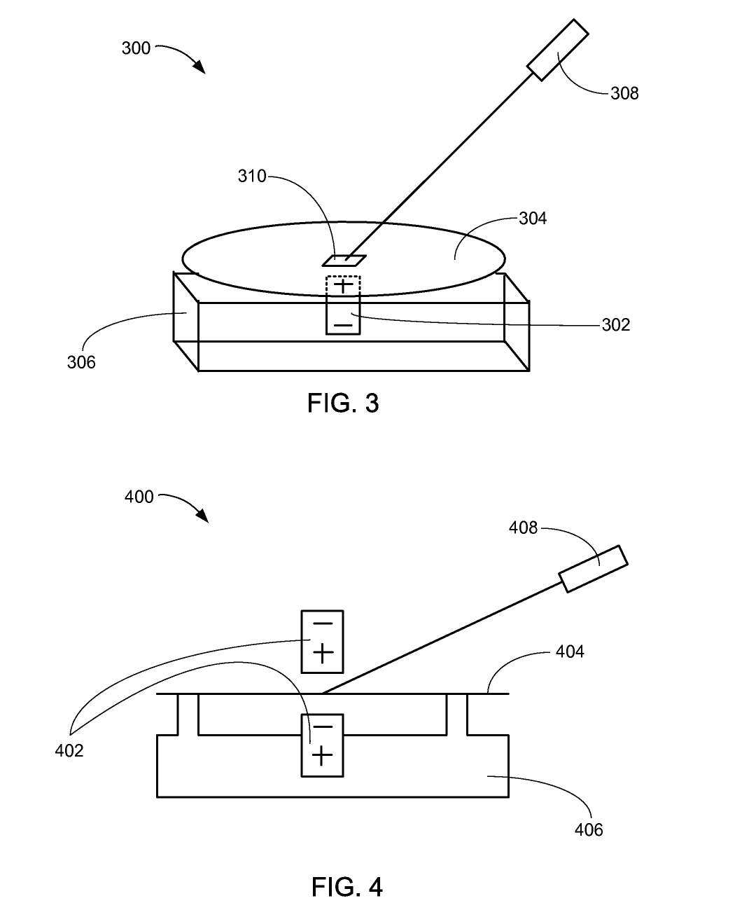

Referring now to FIG. 3, therein is shown an isometric view of the magnetic field guided crystal orientation system 300 in a third embodiment of the present invention. This view shows a magnetic assembly 302, a wafer 304, a work platform 306, and a heating element 308, which are all inside a containment chamber (not shown). The containment chamber is airtight and can be filled with any combination of gases necessary, such as nitrogen, hydrogen, oxygen, argon, helium, other noble gases, or a combination thereof. The wafer 304 is shown with an integrated circuit die 310 before being cut from the wafer 304, though it is understood that the wafer 304 has many of the integrated circuit die 310 across the surface of the wafer 304. The size and location of the integrated circuit die 310 are shown for illustrative purposes only, and it is understood that the integrated circuit die 310 can be a different size or in a different orientation.

Only a portion of the magnetic assembly 302 is shown for clarity. The wafer 304 can be at least 200 mm in diameter and is located above the magnetic assembly 302, which is a magnet mounted below the wafer 304. The wafer 304 is fixed to the work platform 306 while the magnetic assembly 302 is fixed to a separate magnet mount.

The heating element 308 is mounted in a fixed position relative to the magnetic assembly 302 and is capable of generating a beam that can have any cross-sectional shape such as circular, oval, a rectangular or square shape, or polygonal. The heating element 308 can operate in various ways. For example, the heating element 308 can be a laser emitter, an argon beam emitter for physical vapor deposition, electron beam, or a gas cluster ion beam (GCIB). Also for example, the heating element 308 can be a microwave emitter, induction heater, a flash/arc lamp, a broad wavelength flash lamp, or conductive coupling. While other types of beams or heating techniques are possible depending on what is used for the heating element 308, a laser beam is preferred because the laser beam is not affected by magnetic fields. In this example, the laser beam is represented by a solid line extending from the heating element 308 to the wafer 304. It is understood that the solid line can also represent the path of other electromagnetic emissions (ion beam, electron beam, microwaves, etc.).

A laser beam can be generated from the heating element 308 at various wavelengths. The laser beam can be pulsed, continuous wave, or quasi-continuous wave. In this example, the laser beam can be generated with a rectangular or square cross-section in order to “flash” each of the integrated circuit die 310 each time the heating element 308 is pulsed. The work platform 306 can move relative to the heating element 308 and the magnetic assembly 302 to allow full coverage of the wafer 304, and is capable of moving in any direction necessary such as up and down and any kind of lateral movement, in order to position the wafer 304 relative to the laser beam for precisely targeting particular portions of the wafer 304. The heating element 308 is fixed relative to the magnetic assembly 302 so as to have the laser beam illuminate the same spot on the wafer 304 that the magnetic assembly 302 covers with a magnetic field.

The magnetic assembly 302 is capable of generating the magnetic field with a strength of 10 T (Tesla) or more. The magnetic assembly 302 can generate the magnetic field as a static field or as a pulsed magnetic field which is synchronized with the laser beam from the heating element 308. The magnetic assembly 302 can apply the magnetic field uniformly across localized portion of the wafer 304. The magnetic assembly 302 can apply the magnetic field uniformly across a localized portion of the wafer 304. In this example, the magnetic assembly 302 can be fixed relative to the work platform 306. The magnetic assembly 302 is marked with a plus and minus sign for ease of identification only, and the orientation of the plus and minus signs is not meant to be limiting.

It has been discovered that the use of the heating element 308 to generate the laser beam to illuminate a portion of the wafer 304 that is covered by the magnetic field generated by the magnetic assembly 302 allows the simultaneous melt and induction of a preferred crystal orientation upon resolidification of specific types of paramagnetic or diamagnetic metals, such as copper, without the use of a seed crystal. Under the magnetic field of 10 T or greater, many even weakly diamagnetic materials will orient in a specific direction upon solidification.

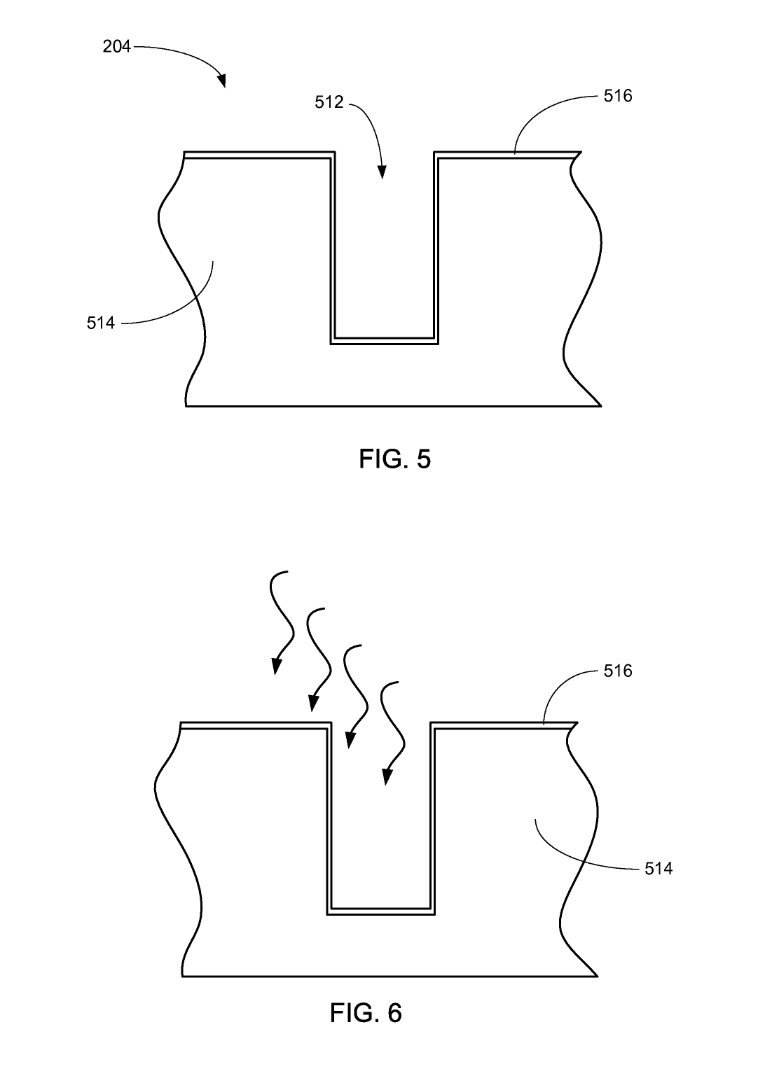

Referring now to FIG. 4, therein is shown a cross-sectional view of the magnetic field guided crystal orientation system 400 in a fourth embodiment of the present invention. This view shows a magnetic assembly 402, a wafer 404, a work platform 406, and a heating element 408, which are all inside a containment chamber (not shown). The containment chamber is airtight and can be filled with any combination of gases necessary, such as nitrogen, hydrogen, oxygen, argon, helium, other noble gases, or a combination thereof. Only a portion of the magnetic assembly 402 is shown for clarity. The wafer 404 can be at least 200 mm in diameter and is located between poles of the magnetic assembly 402, which in this example has magnets mounted above and below the wafer 404. The wafer 404 is fixed to the work platform 406 while the magnetic assembly 402 is fixed to a separate magnet mount. The magnetic assembly 402 can also be a single larger magnet with the poles bent or curved towards the opposite pole with space in between the poles.

The heating element 408 is mounted in a fixed position relative to the magnetic assembly 402 and is capable of generating a beam or heating a specific targeted area that can have any cross-sectional shape such as circular, oval, a rectangular or square shape, or polygonal. For example, the heating element 408 can be positioned to generate a beam at a shallow angle in order to allow the emitted beam a free path to the wafer 404 without occlusion by the portion of the magnetic assembly 402 above the wafer 404. The heating element 408 can operate in various ways. For example, the heating element 408 can be a laser emitter, an argon beam emitter for physical vapor deposition, electron beam, or a gas cluster ion beam (GCIB). Also for example, the heating element 408 can be a microwave emitter, induction heater, a flash/arc lamp, a broad wavelength flash lamp, or conductive coupling. While other types of beams or heating techniques are possible depending on what is used for the heating element 408, a laser beam is preferred because the laser beam is not affected by magnetic fields. In this example, the laser beam is represented by a solid line extending from the heating element 408 to the wafer 404. It is understood that the solid line can also represent the path of other electromagnetic emissions (ion beam, electron beam, microwaves, etc.).

A laser beam can be generated from the heating element 408 at various wavelengths. The laser beam can be pulsed, continuous wave, or quasi-continuous wave. The work platform 406 can move relative to the heating element 408 and the magnetic assembly 402 to allow full coverage of the wafer 404, and is capable of moving in any direction necessary such as up and down and any kind of lateral movement, in order to position the wafer 404 relative to the laser beam for precisely targeting particular portions of the wafer 404. The heating element 408 is fixed relative to the magnetic assembly 402 so as to have the laser beam illuminate the same spot on the wafer 404 that the magnetic assembly 402 covers with a magnetic field. While other types of beams are possible depending on what is used for the heating element 408, a laser beam is preferred because the laser beam is not affected by magnetic fields. For example, the heating element 408 used can be the Applied Materials “ASTRA™” system which generates a scanning laser beam as rectangular or as a stripe, or “Beethoven,” which generates a laser beam as rectangular in a size to match with the size of an integrated circuit die for die-by-die processing.

The magnetic assembly 402 is capable of generating the magnetic field with a strength of 10 T (Tesla) or more. The magnetic assembly 402 can generate the magnetic field as a static field or as a pulsed magnetic field which is synchronized with the laser beam from the heating element 408. The magnetic assembly 402 can apply the magnetic field uniformly across a localized portion of the wafer 404. The magnetic field can be aligned at any direction relative to the wafer 404 such as parallel to the surface, perpendicular to the surface, or at any given angle to the surface. As an alternative example, in order to avoid the problem of an angled laser beam, the magnetic assembly 402 can use a hollow magnet with an opening down the central axis of the magnet for a laser beam to pass through. In this example, the magnetic assembly 402 can be fixed relative to the work platform 406. The various portions of the magnetic assembly 402 are marked with a plus and minus sign for ease of identification only, and the orientation of the plus and minus signs is not meant to be limiting.

It has been discovered that the use of the heating element 408 to generate the laser beam to illuminate a portion of the wafer 404 that is covered by the magnetic field generated by the magnetic assembly 402 allows the simultaneous melt and induction of a preferred crystal orientation upon resolidification of specific types of paramagnetic or diamagnetic metals, such as copper, without the use of a seed crystal. Under the magnetic field of 10T or greater, even weakly diamagnetic materials will crystallographically orient in a specific direction upon resolidification.

Referring now to FIG. 5, therein is shown a detailed cross-sectional view of the wafer 204 in a base layer deposition phase of operation. The process using elements from FIG. 2 is for example only, and it is understood that the process can apply to any embodiment. The cross-sectional view is taken from the side of the wafer, and is not to scale. Wavy lines at the sides of the figure indicate that only a portion of the cross-sectional view is shown. Dimensions are exaggerated for visual clarity only.

A trench 512 (which can also be called an oxide trench) is shown in a wafer substrate 514, which is part of the material out of which the wafer 204 is formed, such as silicon. The trench 512 is a precursor to a portion of an interconnect formed on the wafer 204 and in the wafer substrate 514. The interconnect will later become part of the integrated circuit die 310 of FIG. 3, as an example. The trench 512 in the wafer substrate 514 can be patterned using techniques such as lithography, wet or dry etch, or other patterning process. Other layers (not shown) can be deposited before a base layer 516 such as a barrier layer composed of tantalum nitride.

The trench 512 and other selected surfaces of the wafer substrate can have the base layer 516 deposited uniformly on them as a non-oriented, polycrystalline metal through a process such as physical vapor deposition (PVD), chemical vapor deposition (CVD), atomic layer deposition (ALD), or even electro-chemical plating (ECP, also known as electro-copper plating). The preferred technique is PVD, ALD, or CVD for fine control of thickness. The base layer 516 can be formed of a metal such as copper, tungsten, gold, platinum, silver, manganese, or cobalt at a thickness of just a few nanometers, such as around 2 nm. The base layer 516 can also be formed from graphene or other superconducting materials.

The deposition process is performed optionally within the containment chamber (not shown), and at ambient temperature. The deposition process can be done in an inert or reducing environment to avoid oxidization of the base layer 516. For example, the environment can be argon, hydrogen, helium, other noble gases, or a combination thereof. Also for example, the deposition process can be performed in a forming gas, such as a 1%-10% partial pressure of hydrogen in argon.

Referring now to FIG. 6, therein is shown the structure of FIG. 5 in a base layer alignment phase of operation. The base layer 516 is laid down prior to electro-plating or electroless plating because the growth of the crystal structure of the metal laid down on the base layer 516 will follow the original crystal orientation due to thermodynamics. It is understood that under normal deposition conditions, the base layer 516 will be formed without any particular orientation of the crystals or grains within the base layer 516. Without orienting the grains to a preferred metal direction, any growth of further deposited metal will also lack any particular crystal or grain orientation, which leads to RC delay due to grain boundary scattering.

Application of the laser beam, represented by the wavy arrows, at the proper wavelength depending on the material of the base layer 516 will cause the base layer 516 to melt and then dump the resultant heat into the wafer substrate 514 within nanoseconds or milliseconds, such that only the base layer 516 is melted and no damage to other components occurs. The large difference in thickness of the base layer 516 and the wafer substrate 514 ensures that proper application of a laser beam will melt the material of the base layer 516 without damaging other components.

For some exemplary process configurations, the wavelength of the laser beam should be matched to the material of the base layer 516 for maximum absorbance. For example, if copper is used for the base layer, it has been found that the melting point of copper in a 2 nm layer should be under 400 degrees Celsius (400° C.) and possibly down to around 200-250° C. if the laser beam is generated at around a 550 to 580 nm wavelength. It has been found that at 550 to 580 nm, surface plasmon resonance increases the absorbance of copper, leading to more efficient heating of copper and consequently more efficient melting of a copper nanolayer.

Also for example, shorter wavelengths of the laser beam may be more effective at melting copper once you start going below roughly 400 nm. The choice of wavelength should be driven by practical concerns such as how easy or difficult it is to generate an intense beam at a given wavelength and by the absorbance of the wavelength by the material near a given target temperature. As a further example, some structures of the base layer 516 may be more effectively melted by heating the underlying substrate rather than the base layer 516 directly. This heating of the substrate conductively melts the base layer 516 and allows for longer effective recrystallization times.

It has been discovered that a laser with a wavelength of between 550 and 580 nm can melt copper more effectively than longer or shorter wavelengths until wavelengths go under 400 nm. It is understood by those of ordinary skill in the art that as wavelengths get shorter, it becomes increasingly difficult to increase the power of the laser. The use of a laser with a wavelength between 550 and 580 nm can allow for cheaper and more reliable manufacturing.

The work platform 206 of FIG. 2, for example, can be moved to ensure that the laser beam is not on a single spot of the wafer substrate 514 for too long. As the laser beam, whether pulsed or continuously fired, passes over the trench 512, the laser beam quickly and efficiently can melt the base layer 516. If the laser beam is pulsed, the magnetic assembly 202 of FIG. 2, for example, can be pulsed simultaneously to generate the magnetic field through the portion of the wafer substrate 514 that the laser beam has melted the base layer 516. Pulsing the magnetic field can allow for much stronger magnetic fields of over 10× the level of a static magnetic field. The magnetic assembly 202 can generate a static magnetic field, a pulsed magnetic field, or a combination thereof.

The magnetic field at a high enough strength (around 10 T or higher—pulsed magnets can reach 100 T and up) will align the now flexible crystal structure of the base layer 516, which will quickly resolidify as the laser beam shifts to another location and the heat is dumped into the wafer substrate 514. For example, the crystal structure of the base layer 516 can be aligned to the <111> direction where the <111> direction corresponds to the field lines of the magnetic field generated by the magnetic assembly 202, for example.

It has been discovered that at 10 T, the magnetic field can align the crystal structure of the base layer of copper in the <111> direction, allowing for later crystal growth to follow this <111> direction, and helping to line up grains, reducing grain boundaries. The magnetic field aligns the base layer to the <111> direction, but it is understood that the angle of the magnetic field through the base layer 516 can be adjusted to any angle that gives a good reduction of the RC delay, such as aligning crystals to the <100> in the horizontal. In that example, the magnetic field can be angled at 45° from the horizontal.

The laser beam also can be positioned relative to the surface of the wafer substrate 514 so as to strike the base layer 516 at the Brewster angle, which increases absorbance of the energy from the laser beam (such as a polarized laser beam), allowing more efficient and uniform heating of the base layer 516. The work platform 206 can move such that the laser beam can also be applied to any given portion of the wafer substrate 514 in a nanosecond/millisecond/microsecond range in order to avoid damage to other components and maximize throughput. Dependent on whether the base layer 516 is in the trench or not, the wafer substrate 514 can be around 700 times thicker than the base layer 516, for example. This allows the wafer substrate 514 to act as an effective heat dump due to the large difference in bulk, such that the base layer 516 can heat up quickly and also cool down and resolidify quickly.

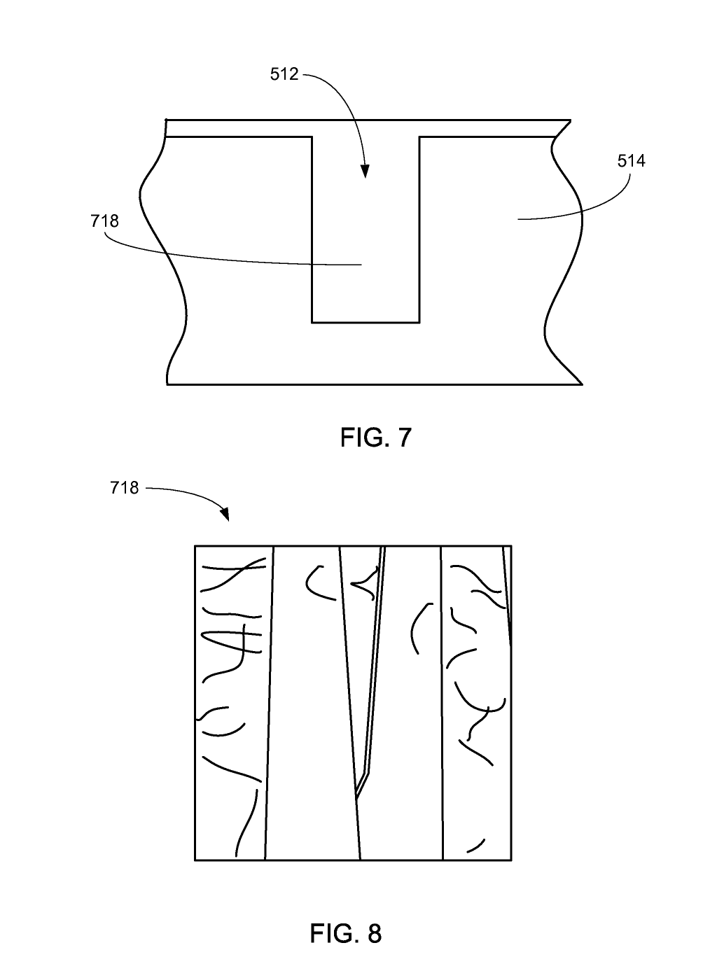

Referring now to FIG. 7, therein is shown the structure of FIG. 6 in a second deposition phase of operation. After alignment of the crystals in the base layer 516 of FIG. 5, the same material as already used in the base layer 516 can be deposited to fill the trench 512 and complete formation of an interconnect 718. For example, copper can be deposited in the trench 512 and over the rest of selected portions of the surface of the wafer substrate 514 to complete the interconnect 718 through a process such as electroplating or electroless plating. Electroless plating is preferred due to better alignment of the crystals through epitaxial growth.

It has been discovered that generating the laser beam to melt the base layer 516 while simultaneously applying a 10 T or greater magnetic field to the base layer allows for reduction in RC delay through the interconnect 718 which is formed by deposition on the base layer 516. The magnetic field will align the crystals of the base layer 516 during recrystallization after the melt to one direction, such as the <111> direction, and the growth of the crystals in the second deposition process will generally follow the crystal orientation of the base layer 516, reducing the grain boundaries between grains of the material forming the interconnect 718, which results in a reduction in RC delay, speeding the transmission of signals through the interconnect 718.

It has also been discovered that alignment of the crystals in the base layer 516 does not need to be perfect in order to reduce RC delay. Before alignment of the crystals, the base layer 516 may have high-angle grain boundaries which increase defects and therefore RC delay. Partially aligning the crystals (or grains) in the base layer 516 to the preferred metal direction can create a situation where the majority of grain boundaries are low-angle grain boundaries which is indicative of reduced defects, resulting in better transmission through reduced RC delay. Grains can have a length dimension that is greater than a width dimension, and aligning the grains along their length in the preferred metal direction can reduce defects.

It has been further discovered that melting the base layer 516 as copper with the laser beam at around 200-250° C. increases throughput of the magnetic field guided crystal orientation system 200, for example, and also increases reliability of the resulting interconnect. The nanometer-scale thickness of the base layer 516 allows a shorter dwell time of the laser beam at any given location on the wafer substrate 514, increasing throughput of the entire system. Further, because the melting temperature of the copper base layer is far below the melting temperature of nearby materials, damage to other components on the wafer is eliminated, increasing reliability. This also allows the laser beam to be rasterized across the entire surface of the wafer 204 of FIG. 2 without concern for damage to other components or structures already present.

Alternatively, the laser beam and magnetic field can be used after the second deposition step. The thickness increase of the copper in the fully formed interconnect will increase the melting temperature, but the thickness should still be small enough to keep the melting temperature around 400° C., which still allows the copper of the interconnect 718 to be aligned without damaging nearby materials or structures.

Referring now to FIG. 8, therein is shown an example of aligned grains of a portion of the interconnect 718. The operation of the magnetic field guided crystal orientation system 200 of FIG. 2 can produce aligned grains, reducing grain boundaries and grain boundary defects. In this example, the crystal orientation of the material of the interconnect 718 is generally in the vertical direction. This would be best for portions of the interconnect 718 where electrical current will run in the vertical direction, for example. The orientation of the grains is for illustrative purposes only, and it is understood that the grains can be aligned in any direction and that partial alignment can also be the result.

It is also understood that partial alignment to get low-angle grain boundaries is also useful to reduce grain boundary defects. The example shows a detailed view of the aligned grains. In this example view, the low-angle grain boundaries are clearly visible.

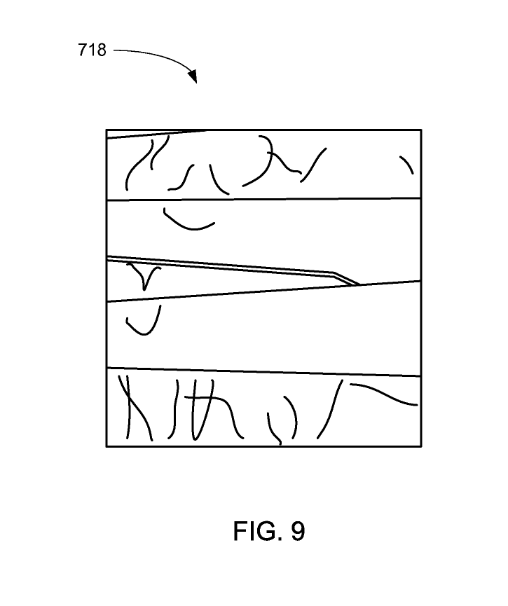

Referring now to FIG. 9, therein is shown another example of aligned grains of a portion of the interconnect 718. The operation of the magnetic field guided crystal orientation system 200 of FIG. 2 can produce aligned grains, reducing grain boundaries and grain boundary defects. In this example, the crystal orientation of the material of the interconnect 718 is generally in the horizontal direction. This would be best for portions of the interconnect 718 where electrical current will run in the horizontal direction, for example. The orientation of the grains is for illustrative purposes only, and it is understood that the grains can be aligned in any direction and that partial alignment can also be the result.

It is also understood that partial alignment to get low-angle grain boundaries is also useful to reduce grain boundary defects. The example shows a detailed view of the aligned grains. In this example view, the low-angle grain boundaries are clearly visible.

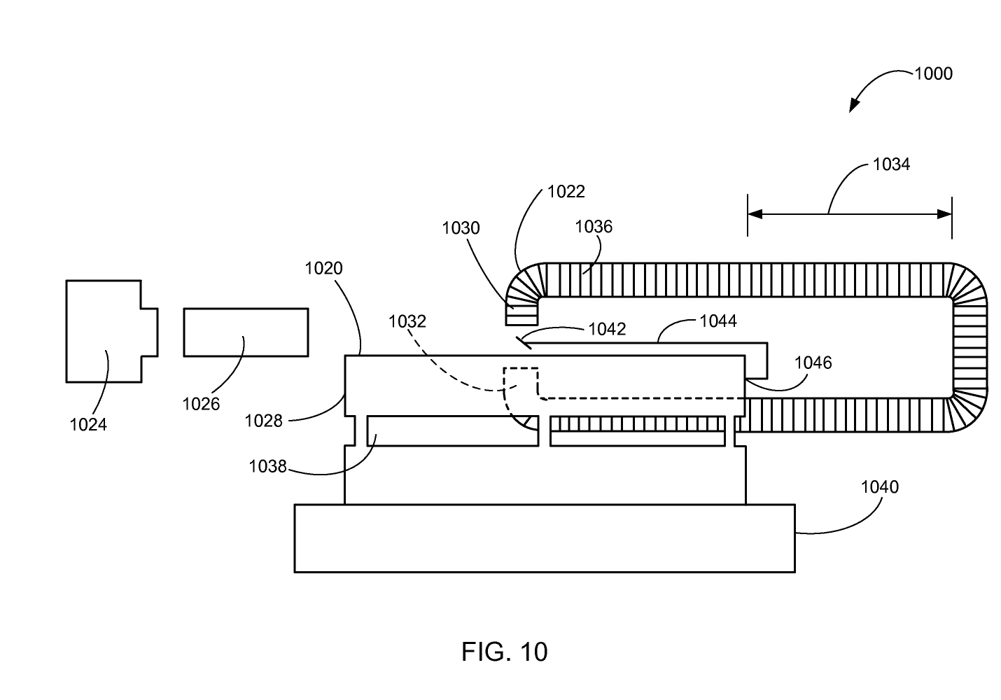

Referring now to FIG. 10, therein is shown the magnetic field guided crystal orientation system 1000 in a fifth embodiment of the present invention. Shown is a schematic view of the magnetic field guided crystal orientation system 1000 with a work surface 1020, a magnetic assembly 1022, a beam source 1024, an optical system 1026, and a substrate support 1028.

The substrate support 1028 holds the substrate, such as a wafer, on the work surface 1020 in place between the poles 1030 and 1032 of the magnetic assembly 1022. The poles 1030 and 1032 are of opposite polarity. The pole 1032 of the magnetic assembly 1022 is shown with dotted lines to indicate how a portion of the magnetic assembly 1022 is partially inside the substrate support 1028.

The wafer is held by the substrate support 1028 to have the magnetic field between the poles 1030 and 1032 of the magnetic assembly 1022 projected through a portion of the wafer. The magnet contains a core and one or more conductive coils 1036. The magnetic assembly 1022 may be a permanent magnet or an electromagnet. The magnetic assembly 1022 is capable of generating a magnetic field of 10 T or greater. The magnetic assembly 1022 as an electromagnet is capable of generating a pulsed magnetic field of 50 T or greater. The magnetic assembly 1022 may be mounted away from the substrate support 1028 and go through the openings 1038 of the substrate support 1028 in order to reach the underside of the substrate or wafer. The magnetic assembly 1022 can have an extension 1034 to allow the substrate support 1028 to move freely while avoiding collisions with the magnetic assembly 1022.

As the substrate support 1028 holding the work surface 1020 and the substrate or wafer move on a stage 1040, different locations on the wafer are exposed to the beam from the beam source 1024. The magnetic assembly 1022 and a waveguide 1042 are fixed with respect to each other such that they cover the same portion of the substrate or wafer at the same time.

The beam source 1024 generates electromagnetic radiation, including visible light, and the optical system 1026 modifies the shape, uniformity, overall intensity, spectral distribution. For example, the optical system 1026 can serve to focus the beam from the beam source 1024. The waveguide 1042 directs the beam from the beam source 1024 onto the substrate or wafer, and may have components such as mirrors, retroreflectors, partial reflectors, refractors, or optical fibers. More than one of the waveguide 1042 can be used. The waveguide 1042 is supported by a waveguide support 1044 attached to a stationary fixture such as a chamber wall 1046 of a containment chamber.

It has been discovered that the use of the beam source 1024 to generate the laser beam to illuminate a portion of the wafer that is covered by the magnetic field generated by the magnetic assembly 1022 allows the simultaneous melt and induction of a preferred crystal orientation upon resolidification of specific types of materials other than ferromagnetic materials such as paramagnetic or diamagnetic metals, such as copper, without the use of a seed crystal. Under the magnetic field of 10 T or greater, even weakly diamagnetic materials will crystallographically orient in a specific direction upon solidification. Note that it may also be advantageous to perform a stair-case reduction in temperature as the resolidification cooling takes place, so, for example, the laser pulses (or arc lamp flashes) may be delivered such that a first pulse (or set of pulses) melts the metal, and then a series of decreasing intensity pulses is delivered to engineer specific cooling profiles.

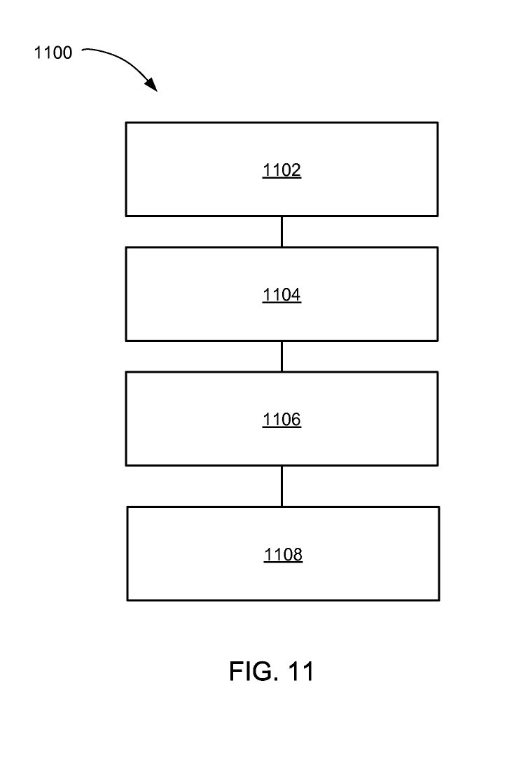

Referring now to FIG. 11, therein is shown a flow chart of a method 1100 of operation of a magnetic field guided crystal orientation system in a further embodiment of the present invention. The method 1100 includes: providing a wafer including a wafer substrate in a block 1102; depositing a base layer having grains on the wafer substrate in a block 1104; aligning the crystal orientation of the grains of the base layer using a magnetic field of 10 Tesla or greater in a block 1106; and forming an interconnect on the base layer, the crystal orientation of the grains in the interconnect matching the crystal orientation of the grains of the base layer in a block 1108.

The resulting method, process, apparatus, device, product, and/or system is straightforward, cost-effective, uncomplicated, highly versatile, accurate, sensitive, and effective, and can be implemented by adapting known components for ready, efficient, and economical manufacturing, application, and utilization.

Another important aspect of the present invention is that it valuably supports and services the historical trend of reducing costs, simplifying systems, and increasing performance.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of operation of a magnetic field guided crystal orientation system comprising:
providing a wafer including a wafer substrate;
depositing a base layer having grains on the wafer substrate;
aligning the crystal orientation of the grains of the base layer using a magnetic field of 10 Tesla or greater; and
forming an interconnect on the base layer, the crystal orientation of the grains in the interconnect matching the crystal orientation of the grains of the base layer.

2. The method as claimed in claim 1 further comprising:
melting the base layer using a heating element.

3. The method as claimed in claim 1 wherein aligning the crystal orientation of the grains of the base layer includes:
aligning the crystal orientation of the grains of the base layer using the magnetic field while the base layer is in a melted state for forming low-angle grain boundaries; and
allowing the base layer to solidify after aligning the crystal orientation of the grains of the base layer.

4. The method as claimed in claim 1 further comprising:
generating the magnetic field with a magnetic assembly.

5. The method as claimed in claim 1 wherein providing the wafer including the wafer substrate includes:
providing the wafer substrate having a trench.

6. A method of operation of a magnetic field guided crystal orientation system comprising:
providing a wafer including a wafer substrate having a trench;
depositing a base layer having grains in the trench and on the wafer substrate;
melting the base layer with a heating element;
generating a magnetic field of 10 Tesla or greater with a magnetic assembly;
aligning the crystal orientation of the grains of the base layer using the magnetic field while the base layer is in a melted state for forming low-angle grain boundaries;
allowing the base layer to solidify after aligning the crystal orientation of the grains of the base layer; and
forming an interconnect on the base layer and in the trench, the crystal orientation of the grains in the interconnect matching the crystal orientation of the grains of the base layer.

7. The method as claimed in claim 6 wherein depositing the base layer includes depositing diamagnetic or paramagnetic materials.

8. The method as claimed in claim 6 wherein depositing the base layer includes depositing diamagnetic or paramagnetic materials selected from the group of copper, gold, tungsten, platinum, or manganese.

9. The method as claimed in claim 6 wherein melting the base layer with a heating element includes melting the base layer with a laser having a wavelength between 550 nm and 580 nm.

10. The method as claimed in claim 6 wherein allowing the base layer to solidify includes engineering a specific cooling profile including:
melting the base layer with a first pulse or set of pulses from the heating element; and
decreasing the intensity of later pulses from the heating element.

11. A magnetic field guided crystal orientation system comprising:
a work platform;
a heating element above the work platform for selectively heating a base layer having grains on a wafer substrate where the wafer substrate is a part of a wafer on the work platform; and
a magnetic assembly fixed relative to the heating element for aligning the grains of the base layer using a magnetic field of 10 Tesla or greater for formation of an interconnect having a crystal orientation of grains in the interconnect matching the crystal orientation of the grains of the base layer.

12. The system as claimed in claim 11 wherein the heating element is for melting the base layer using the heating element.

13. The system as claimed in claim 11 wherein:
the magnetic assembly is for aligning the crystal orientation of the grains of the base layer using the magnetic field while the base layer is in a melted state for forming low-angle grain boundaries; and
the heating element has an adjustable intensity of output for alignment of the crystal orientation of the grains of the base layer.

14. The system as claimed in claim 11 wherein the magnetic assembly is for generating the magnetic field.

15. The system as claimed in claim 11 wherein the wafer substrate has a trench.

16. The system as claimed in claim 11 wherein:
the heating element is for:
melting the base layer using the heating element; and
the magnetic assembly is for:
generating the magnetic field, and
aligning the crystal orientation of the grains of the base layer using the magnetic field while the base layer is in a melted state for forming low-angle grain boundaries.

17. The system as claimed in claim 16 wherein the base layer includes diamagnetic or paramagnetic materials.

18. The system as claimed in claim 16 wherein the base layer includes diamagnetic or paramagnetic materials selected from the group of copper, gold, tungsten, platinum, or manganese.

19. The system as claimed in claim 16 wherein the heating element is a laser for melting the base layer with the laser having a wavelength between 550 nm and 580 nm.

20. The system as claimed in claim 16 wherein the heating element is for engineering a specific cooling profile including:
melting the base layer with a first pulse or set of pulses from the heating element; and
decreasing the intensity of later pulses from the heating element.
